(19) United States
(12) Patent Application Publication
(10) Pub. No.: US 2026/0150605 A1
(43) Pub. Date: May 28, 2026

(54) METHODS FOR SUBSTRATE PROCESSING

(71) Applicant: ASM IP Holding B.V., Almere (NL)

(72) Inventors: Madhan Kumar Arulanandam, Tempe, AZ (US); Andrew O'Reilly, Chandler, AZ (US); Balaji Kannan, Phoenix, AZ (US); DoHan Kim, Phoenix, AZ (US)

(21) Appl. No.: 19/398,183

(22) Filed: Nov. 24, 2025

Related U.S. Application Data
(60) Provisional application No. 63/725,704, filed on Nov. 27, 2024.

(51) Int. Cl. H01L 21/467; H01L 21/02

(52) U.S. Cl. CPC H10P 50/69; H10P 14/3434

(57) ABSTRACT

A method can comprise performing an etch cycle on a transition metal film deposited on a substrate. The etch cycle can comprise oxidizing the transition metal film, and/or etching the oxidized transition metal film with an etchant comprising a metal halogen compound. A method can comprise depositing an indium gallium zinc oxide (IGZO) film on a substrate, and/or etching the IGZO film with a first etchant comprising a metal halide.

### CROSS-REFERENCE TO RELATED APPLICATIONS

This application is a nonprovisional of, and claims priority to and the benefit of, U.S. Provisional Patent Application No. 63/725,704, filed Nov. 27, 2024 and entitled “METHODS FOR SUBSTRATE PROCESSING,” which is hereby incorporated by reference herein.

### FIELD

The present disclosure generally relates to the field of film processing (e.g., deposition and etch) in reactor systems.

### BACKGROUND

Etchants used in film processing (e.g., for semiconductor film processing) can be selective for certain compounds. Accordingly, preparing a deposited film for etch (e.g., via chemical reaction) can be beneficial. Further, selective film formation and/or etching can facilitate formation of desired structures, geometries, layers, and/or the like.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Examples described herein provide methods of film deposition and/or etch on a substrate. For example, a method can comprise performing an etch cycle on a transition metal film deposited on a substrate. The etch cycle can comprise oxidizing the transition metal film, and/or etching the oxidized transition metal film with an etchant comprising a metal halogen compound. The transition metal film can comprise at least one of a transitional metal nitride or a transition metal. The method can further comprise repeating the etch cycle multiple times. In an etch cycle, the step of oxidizing the transition metal film is repeated a desired number of times and/or the step of etching the oxidized transition metal film step is repeated a second desired number of times. The transition metal film can comprise a transition metal nitride comprising at least one of titanium nitride, vanadium nitride, or nickel nitride, and/or the transition metal film can comprise a transition metal comprising molybdenum. The etchant can comprise at least one of tungsten pentachloride, niobium chloride, or molybdenum chloride. Oxidizing the transition metal film can comprise applying at least one of oxygen (O₂), ozone, peroxide, nitrous oxide, an alcohol, or water to the transition metal film.

In various examples, before performing an etch cycle, the method can further comprise depositing an indium gallium zinc oxide (IGZO) film on the substrate, selectively forming the transition metal film on a first portion of the IGZO film, and/or selectively etching a second portion of the IGZO film with a first etchant comprising a metal halide. The second portion of the IGZO film may not comprise the transition metal film deposited thereon. The first etchant can comprise tungsten pentachloride.

In various examples, a method can comprise depositing an indium gallium zinc oxide (IGZO) film on a substrate, and/or etching the IGZO film with a first etchant comprising a metal halide. The first etchant can comprise tungsten pentachloride. The method can further comprise selectively forming a transition metal film on a first portion of the IGZO film before the etching the IGZO film step, wherein the etching the IGZO film step comprises selectively etching a second portion of the IGZO film, wherein the second portion of the IGZO film does not comprise the transition metal film deposited thereon. The transition metal film can comprise at least one of a transitional metal nitride (e.g., titanium nitride, vanadium nitride, and/or nickel nitride) or a transition metal (e.g., molybdenum).

In various examples, before etching the IGZO film, the method can further comprise depositing a transition metal film onto the IGZO film, wherein the transition metal film comprises at least one of a transitional metal nitride or a transition metal, and/or selectively etching the transition metal film from a second portion of the IGZO film, such that the transition metal film is removed from the second portion of the IGZO film and the transition metal film is maintained on a first portion of the IGZO film. The method can further comprise oxidizing the transition metal film before selectively etching the transition metal film, wherein selectively etching the transition metal film can comprise etching the oxidized transition metal film with an etchant comprising a metal halogen compound. The etchant can comprise tungsten pentachloride, niobium chloride, and/or molybdenum chloride.

In various examples, a method can comprise depositing an indium gallium zinc oxide (IGZO) film in a gap feature of a substrate, creating a seam in the gap feature in response to the depositing the IGZO film, etching the IGZO film with an etchant comprising tungsten pentachloride to expose the seam, and/or depositing a second IGZO film to fill the seam, such that the gap feature is filled with IGZO material without formation of a (e.g., visible) seam.

For the purpose of summarizing the disclosure and the advantages achieved over the prior art, certain objects and advantages of the disclosure have been described herein above. Of course, it is to be understood that not necessarily all such objects or advantages may be achieved in accordance with any particular embodiment of the disclosure. Thus, for example, those skilled in the art will recognize that the disclosure may be embodied or carried out in a manner that achieves or optimizes one advantage or group of advantages as taught or suggested herein without necessarily achieving other objects or advantages as may be taught or suggested herein

All of these embodiments are intended to be within the scope of the disclosure herein disclosed. These and other embodiments will become readily apparent to those skilled in the art from the following detailed description of certain embodiments having reference to the attached figures, the disclosure not being limited to any particular embodiment(s) disclosed.

### BRIEF DESCRIPTION OF THE DRAWINGS

While the specification concludes with claims particularly pointing out and distinctly claiming what are regarded as examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1 illustrates a schematic diagram of a reactor system, in accordance with various examples.

FIG. 2 illustrates a processing method, in accordance with various examples.

FIG. 3 illustrates another processing method, in accordance with various examples.

FIG. 4 illustrates another processing method, in accordance with various examples.

FIG. 5A depicts plots showing an etched thickness versus the number of etch cycles, in accordance with various examples.

FIG. 5B depicts a plot showing an etched thickness versus the number of etch steps, in accordance with various examples.

FIG. 5C depicts a plot showing an etched film thickness versus the number of etch steps, in accordance with various examples.

FIG. 6A illustrates a substrate having a film deposited thereon, in accordance with various examples.

FIG. 6B illustrates the substrate of FIG. 6A after being exposed to an etch cycle(s), in accordance with various examples.

FIG. 7A illustrates a substrate having a film deposited thereon, in accordance with various examples.

FIG. 7B illustrates a substrate after being exposed to an etch cycle(s) utilizing a relatively more reactive oxidant, in accordance with various examples.

FIG. 7C illustrates a substrate after being exposed to an etch cycle(s) utilizing a relatively less reactive oxidant, in accordance with various examples.

FIG. 8 depicts a plot showing an etched film thickness versus number of etch steps, in accordance with various examples.

FIG. 9 illustrates a process of filling a void in a substrate, in accordance with various examples.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof may be combined or may be applied separately from each other. Methods may include the disclosed steps in any suitable and/or desired order or combination.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, but do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material.

In some examples, “film” refers to a layer extending in a direction perpendicular to a thickness direction. In some examples, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “cyclical” deposition or etch process or “cyclic” deposition or etch process can refer to a vapor deposition process in which deposition or etch cycles, typically a plurality of consecutive deposition or etch cycles, are conducted in a process chamber. Cyclic deposition or etch processes can include, for example, cyclic chemical vapor deposition (CCVD) and/or atomic layer deposition (ALD) processes. Cyclic deposition or etch processes can include plasma-enhanced steps. A cyclic deposition or etch process can include one or more cycles that include plasma activation of a precursor, a reactant, and/or an inert gas in any combination.

In this disclosure, any two numbers of a variable can constitute a workable range of the variable, any ranges indicated may include or exclude the endpoints, and all ranges and ratio limits disclosed herein may be combined. Additionally, any values of variables indicated (regardless of whether they are indicated with “about” or not) may refer to precise values or approximate values and include equivalents, and may refer to average, median, representative, majority, etc. in some examples. Unless specifically stated otherwise, references to “a,” “an,” and/or “the” may include one or more than one, and references to an item in the singular may also include the item in the plural. When referring to components of systems discussed herein, the term “coupled” refers to direct coupling or indirect coupling with other intervening elements, as appropriate. Unless otherwise indicated, the terms “first,” “second,” etc., and/or “primary,” “secondary,” etc., are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item. Further, reference to, e.g., a “first” item and a “second” item does not mean that there are no intervening items, and such intervening items may be present.

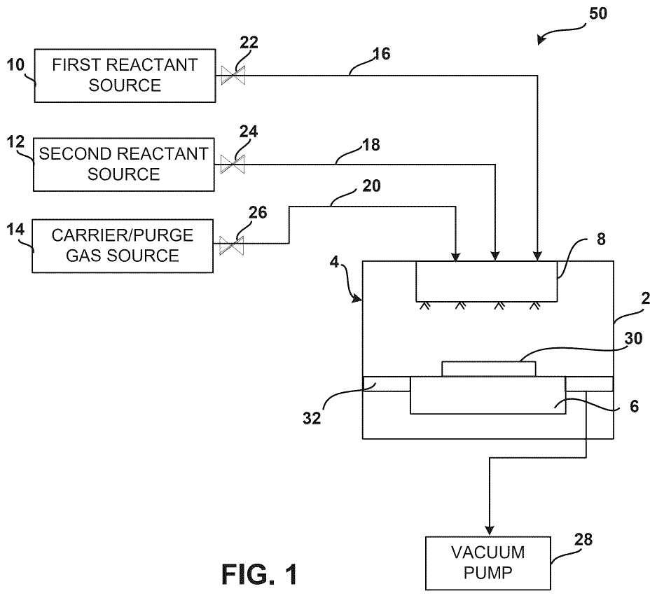

Reactor systems used for ALD, CVD, and/or the like, may be used for a variety of applications, including depositing and etching materials on a substrate surface. In various embodiments, as depicted in FIG. 1, a reactor system 50 can comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or a carrier and/or purge gas source 14, fluidly coupled to reaction chamber 4 via lines 16-20, and valves or controllers 22-26. Reactant gases or other materials from reactant sources 10, 12 can be applied to substrate 30 in reaction chamber 4. A purge gas from purge gas source 14 can be flowed to and through reaction chamber 4 to remove any excess reactant or other undesired materials from reaction chamber 4. System 50 can also comprise a vacuum source 28 fluidly coupled to the reaction chamber 4, which can be configured to evacuate reactants, a purge gas, or other materials out of reaction chamber 4.

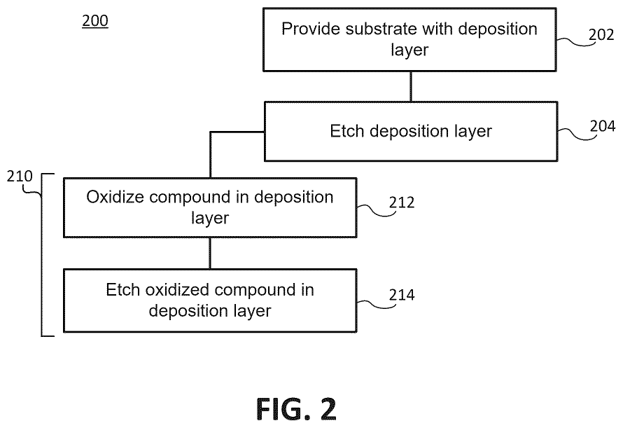

FIG. 2 illustrates a processing method 200. Method 200 can comprise a method for etching a deposition layer on a substrate (e.g., in a reaction chamber). Method 200 can include providing a substrate with a deposition layer (step 202), e.g., into a reaction chamber, and etching the deposition layer (step 204). An etch cycle 210 can be performed on the deposition layer for etch step 204 to remove at least a portion of the deposition layer.

The deposition layer can comprise a transition metal film. A transition metal film can comprise a transition metal (e.g., elemental metal), for example, molybdenum, and/or transition metal nitride, for example, titanium nitride, nickel nitride, and/or vanadium nitride.

An etchant to etch a transition metal film (as part of step 204) can comprise a transition metal halogen (e.g., a transition metal chloride). For example, the etchant can comprise tungsten pentachloride, niobium chloride, molybdenum chloride, titanium chloride, vanadium chloride, ruthenium chloride, tantalum chloride, and/or hafnium chloride. Etchants comprising a transition metal chloride can be selective for certain compounds over others, for example, having greater affinity to etch a metal oxide over a metal, metal nitride, or other compound. Accordingly, an etch cycle 210 can comprise oxidizing a compound in the deposition layer (step 212) and etching the oxidized compound in the deposition layer (step 214). Step 212 can comprise applying an oxidizer to the deposition layer. For example, the oxidizer can comprise oxygen (O₂), ozone, peroxide, nitrous oxide, an alcohol, and/or water. Titanium nitride in a transition metal film can be oxidized to titanium oxide. Nickel nitride in a transition metal film can be oxidized to nickel oxide. Vanadium nitride in a transition metal film can be oxidized to vanadium oxide. Molybdenum in a transition metal film can be oxidized to molybdenum oxide (MoO₂ and/or MoO₃). The oxidized deposition layer can then be etched with the etchant (step 214).

The etch cycle 210 can be repeated any desired number of times (e.g., to achieve a desired etch level or layer thickness). Step 212 can be repeated any suitable number of times within an etch cycle 210 relative to step 214. Step 214 can be repeated any suitable number of times within an etch cycle 210 relative to step 212.

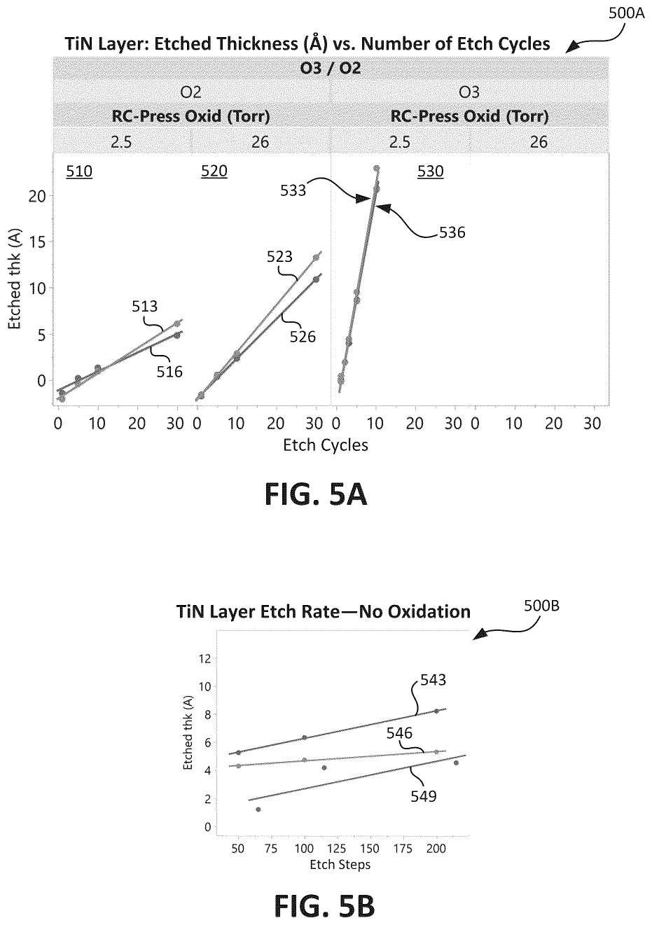

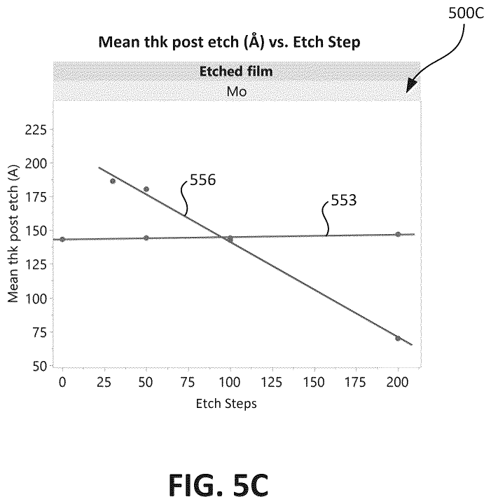

Etch cycle 210 can allow in-situ processing (e.g., within a single reaction chamber), allowing repetition of etch cycle 210 and/or each of steps 212 or 214 any desired number of times. Such processing can be more efficient than a process utilizing multiple reaction chambers (e.g., a different reaction chamber for different steps), decreasing time between processing steps and increasing throughput. Additionally, etch cycle 210 can allowed controlled etch of the deposition layer. FIG. 5A shows that a transition metal film can have a linear etch rate utilizing etch cycle 210. Chart 500A depicts the etched thickness (Å) (y-axis) versus the number of etch cycles 210 (x-axis) performed on a transition metal film comprising titanium nitride. The etchant used comprises tungsten pentachloride. As depicted, plots 510 and 520 utilized oxygen gas (O₂) as an oxidizer, and plot 530 utilized ozone (O₃) as an oxidizer. Ozone, being a more reactive compound and oxidizer than oxygen, results in a greater etch rate than oxygen as the oxidizer. As shown, the etch rate is linear, allowing predictability and controllability of layer etch. Data sets 513, 523, and 533 have a ratio of oxidize step 212 to etch step 214 of 1:10 per etch cycle 210. Data sets 516 and 526 have a ratio of oxidize step 212 to etch step 214 of 1:8 per etch cycle 210. Data set 536 has a ratio of oxidize step 212 to etch step 214 of 1:9 per etch cycle 210. Thus, a greater number of etch steps 214 relative to the oxidation steps 212 in an etch cycle 210 can result in a greater etch rate.

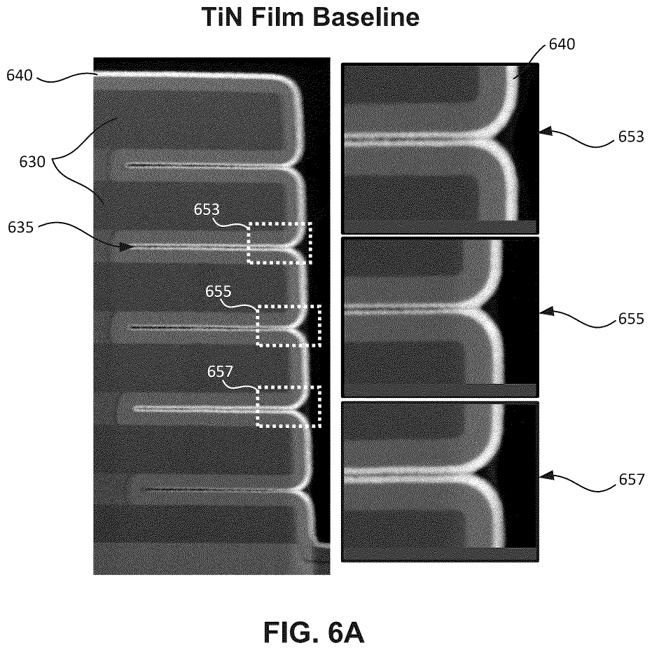

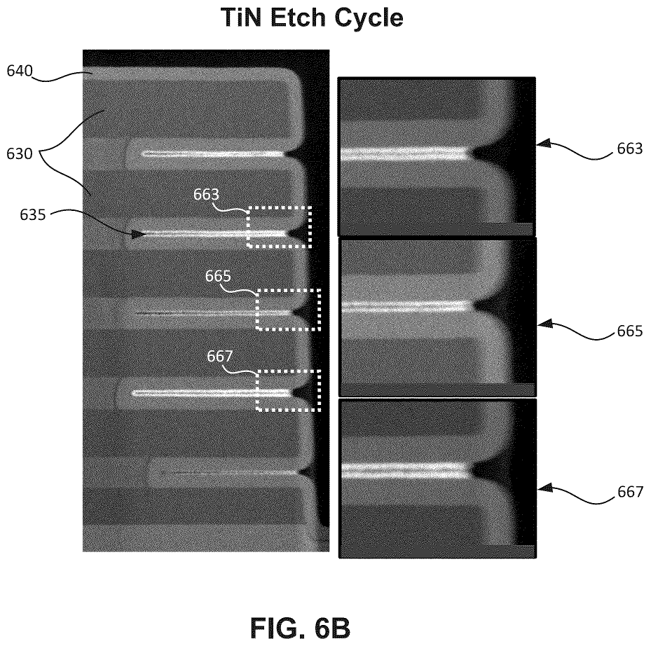

With reference to FIGS. 6A and 6B, a substrate having a transition metal nitride film through an etch process is depicted, in accordance with various examples. As shown, substrate 630 has trench features 635, and a titanium nitride film 640 is deposited on substrate 630 and within trench features 635. FIG. 6A depicts substrate 630 with titanium nitride film 640 before an etch process is performed (magnified views of portions 653, 655, and 657 of substrate 630 are provided). FIG. 6B depicts substrate 630 with titanium nitride film 640 after etch cycle 210 being performed thereon (magnified views of portions 663, 665, and 667 of substrate 630 are provided). An oxidant (e.g., comprising ozone and/or oxygen (O₂)) and an etchant comprising tungsten pentachloride were used. As shown, various portions of titanium nitride film 640 have been removed from substrate 630 (e.g., at least from portions outside of trench features 635 and at the inlets of trench features 635).

As evidenced by FIGS. 5A-5C, the etch rate of a titanium nitride layer is increased by the inclusion and performance of oxidation step 212 in etch cycle 210. FIG. 5B depicts a chart 500B showing the etch thickness (Å) (y-axis) of a titanium nitride film versus the number of etch steps (without an oxidation step(s)). The etchant used comprises tungsten pentachloride. Data set 543 represents processing conducted at 350° F. Data set 546 represents processing conducted at 400° F. Data set 549 represents processing conducted at 300° F. As shown, the etch rates of data sets 543, 546, and 549 are significantly lower relative to the etch rates achieved by etch cycle 210 including oxidation step 212, in accordance with this disclosure. FIG. 5C depicts a chart 500C showing the mean film thickness post-etch (y-axis) versus the number of etch steps (x-axis) (i.e., film thickness after each etch step). Data set 553 represents a process including only etch steps without any oxidation steps. Data set 556 represents a process including etch cycles 210 with a ratio of oxidize step 212 to etch step 214 of 1:10 per etch cycle 210, with the oxidant comprising ozone. As shown, the etch rate of data set 556 has a significantly greater etch rate than the etch rate of data set 553 (which has no oxidation step).

In various examples, isotropic or substantially isotropic etch of a film on a substrate may be desired (e.g., within trench features and in the field of the substrate). In this context, “substantially” means within plus or minus 10% or 20% of completely isotropic. The “field” of a substrate can be the portion outside of any trench features (e.g., the “surface” of a substrate between the trench features). The field of a substrate can include inlets of trench features, for example, the wider portions of the trench transitioning into the narrower portions. In various examples, anisotropic etch of a film on a substrate may be desired (e.g., desiring greater etch of the film field relative to within the trench features).

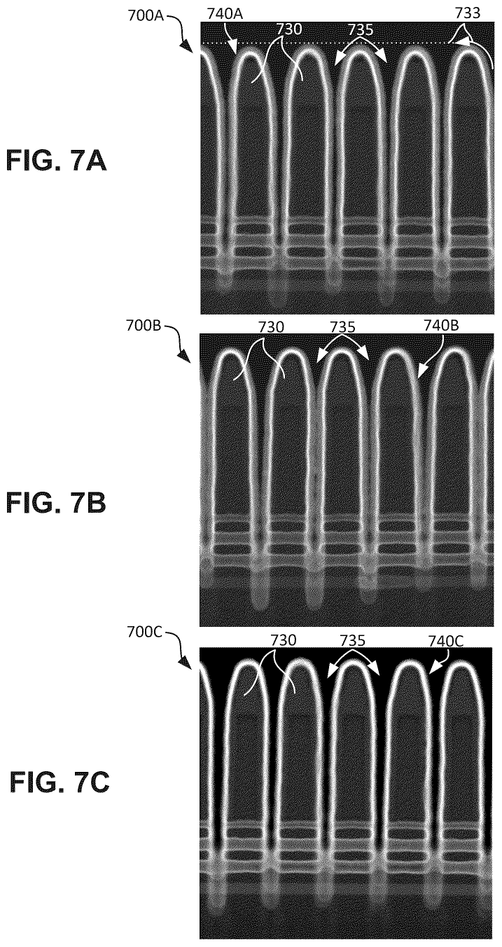

Relatively more reactive oxidants, such as ozone, can result in greater etch of a film on the field of a substrate relative to within trench features. Without being bound by theory, a more reactive oxidant has a shorter lifetime than less reactive oxidants. Accordingly, a more reactive oxidant may react (oxidize) portions of a film more readily accessible and/or closer to the oxidant source (e.g., portions of the film on a substrate field). Thus, the oxidized portions will be more readily etched utilizing etch cycle 210. For example, FIG. 7A depicts a control structure 700A including a substrate 730 having a field 733, trench features 735, and a titanium nitride film 740A disposed on substrate 730, including within trench features 735. Structure 700A depicts titanium nitride film 740A without an etch process being performed thereon. In response to conducting etch cycle 210 on a structure comprising a titanium nitride film (similar to structure 700A), utilizing a relatively more reactive oxidant comprising ozone, as depicted in FIG. 7B, titanium nitride film 700B is etched to a greater degree in field 733, and to a lesser degree in trench features 735 (or not etched at all).

Beginning again with a structure comprising a titanium nitride film (similar to structure 700A), utilizing a relatively less reactive oxidant comprising oxygen gas (O₂), peroxide, an alcohol, water, nitrous oxide, and/or the like, can result in substantially isotropic etch of film 740A. Without being bound by theory, a relatively less reactive oxidant has a longer lifetime than more reactive oxidants, and thus can flow into a trench feature of a substrate before reacting, thus reacting with (oxidizing) the film within and/or throughout the trench feature. For example, in response to conducting etch cycle 210 on the substrate having a titanium nitride film, utilizing a relatively less reactive oxidant comprising oxygen gas, as depicted in FIG. 7C, titanium nitride film 700C is etched in a substantially isotropic manner between field 733 and trench features 735. Accordingly, selecting the oxidant based on reactivity can allow greater control of the etch pattern on a substrate.

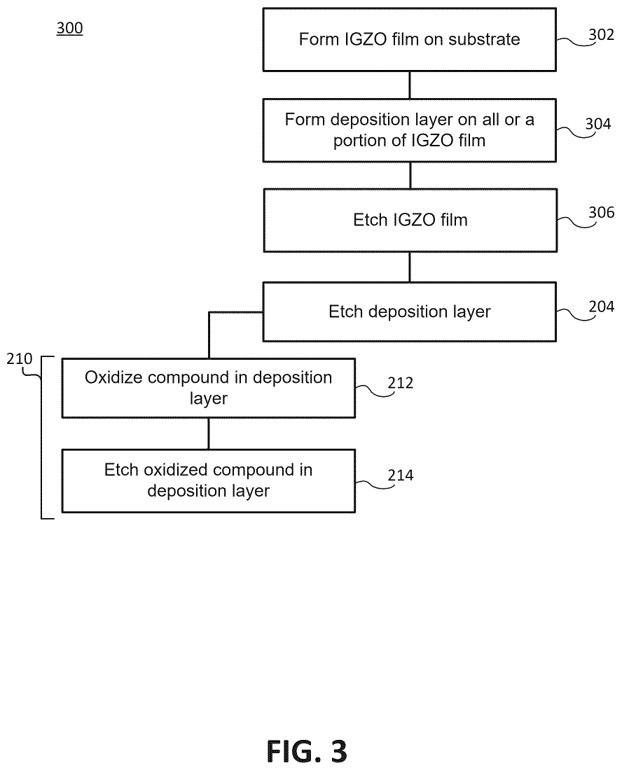

With additional reference to FIG. 3, a method 300 can comprise forming an indium gallium zinc oxide (IGZO) film on a substrate (step 302) and/or etching the IGZO film (step 306). The IGZO film can comprise any suitable form or variation of IGZO. For example, an IGZO film can comprise a tin dopant and/or an aluminum dopant. The tin and/or aluminum dopants can be elemental metals. The film can comprise an IGO compound or film (indium gallium oxide), an IZO compound or film (indium zinc oxide), and/or a GZO compound or film (gallium zinc oxide). Reference to an IGZO film herein can include any of these IGZO variant films. The etchant for etching step 306 can comprise a metal halide (which can be a reactant or precursor compound). For example, the metal halide can comprise a metal chloride such as tungsten pentachloride, niobium chloride, and/or molybdenum chloride. Etching step 306, and the etchant used therein, can be free of plasma and/or a second precursor. The etchant used can be a single precursor or compound. Etching of an IGZO film may be free to an oxidizing step.

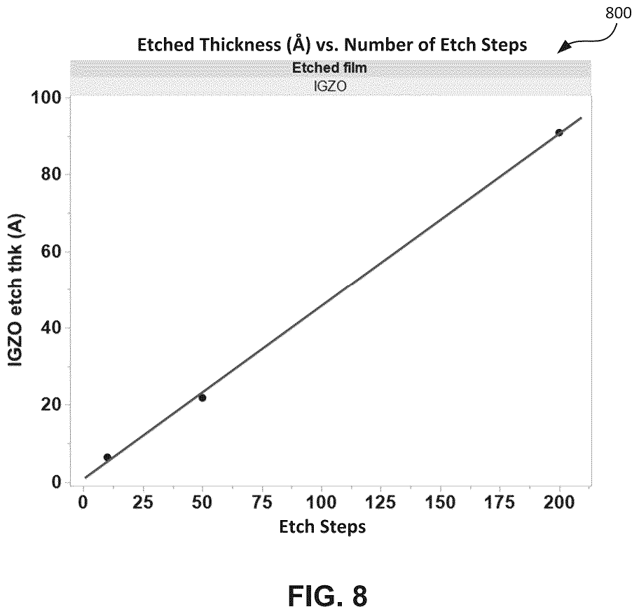

With additional reference to FIG. 8, chart 800 depicts the etched thickness (Å) of a film (y-axis) versus the number of etch steps 306 (x-axis) performed on an IGZO film at 350° C. The etchant used comprised tungsten pentachloride. As shown, the etch rate of using a metal halide (e.g., a metal chloride) etchant on an IGZO film is linear, thus allowing controllable and predictable etching.

With reference again to FIG. 3, method 300 can comprise forming a deposition layer on all or a portion of the IGZO film (step 304). Step 304 can occur after forming the IGZO film on a substrate (step 302) and/or before etching the IGZO film (step 306). The deposition layer of step 304 can the similar to, or the same as, the deposition layer discussed in relation to method 200, thus the discussion thereof can be applied to the deposition layer in method 300. The deposition layer can comprise a transition metal film (e.g., a metal or metal nitride). Deposition of the transition metal film on the IGZO film can allow selective etching of the IGZO film.

For example, a transition metal film can be selectively formed on a first portion of the underlying IGZO film (step 304). The transition metal film can be selectively formed in any suitable manner. For example, a photoresist method can be employed, in which a photoresist layer, comprising a light-sensitive material (e.g., comprising diazonaphthoquinone, poly(methyl methacrylate), and/or any other suitable material or compound), can be disposed on the IGZO film. A mask can cover a second portion of the IGZO film and the photoresist layer, exposing a first portion of the photoresist layer that is aligned with the first portion of the IGZO film. Light can be directed toward the substrate such that light is applied to the first portion of the photoresist layer, which can remove the first portion of the photoresist layer. Light may not be applied to the second portion of the photoresist layer because of the mask. Then the transition metal film can be formed on the first portion of the IGZO film from which the photoresist layer was removed, and the second portion of the IGZO film may not receive the transition metal film formed thereon because of the photoresist layer remaining on the second portion of the IGZO film. The remaining photoresist layer on the second portion of the IGZO film can be removed leaving the transition metal film selectively formed on the first portion of the IGZO film.

As another example of a photoresist method, a light-sensitive material can be disposed on the IGZO film (e.g., over all of the IGZO film). A mask can cover a first portion of the photoresist layer that is aligned with the first portion of the IGZO film, exposing a second portion of the photoresist layer that is aligned with a second portion of the IGZO film. Light can be directed toward the substrate such that light is applied to the second portion of the photoresist layer, which can toughen the second portion of the photoresist layer (i.e., make the second portion etch-resistant). Light may not be applied to the first portion of the photoresist layer because of the mask. Then the first portion of the photoresist layer can be removed (e.g., via an etch process), exposing the IGZO film aligned therewith. Then the transition metal film can be formed on the first portion of the IGZO film from which the photoresist layer was removed, and the second portion of the IGZO film may not receive the transition metal film formed thereon because of the photoresist layer remaining on the second portion of the IGZO film. The remaining photoresist layer over the second portion of the IGZO film can be removed leaving the transition metal film selectively formed on the first portion of the IGZO film.

As another example of step 304 in method 300, a transition metal film can be formed on the IGZO film (e.g., covering all substantially all of the IGZO film). Then, a second portion of the transition metal film aligned with a second portion of the IGZO film can be selectively etched, such that a first portion of the transition metal film remains on the IGZO film aligned with a first portion thereof. The selective etching can be accomplished via, for example, a photoresist process, similar to the photoresist process described above.

As an example of a photoresist method, a photoresist layer, comprising a light-sensitive material, can be disposed on the transition metal film. A mask can cover a portion of the photoresist layer aligned with a first portion of the IGZO film and the transition metal film, exposing a second portion of the photoresist layer that is aligned with a second portion of the IGZO film and transition metal film. Light can be directed toward the substrate such that light is applied to the second portion of the photoresist layer, which can remove the second portion of the photoresist layer. Light may not be applied to the first portion of the photoresist layer because of the mask. Then the second portion of the transition metal film can be etched (e.g., via etch step 204 including etch cycle 210) from which the photoresist layer was removed, and the first portion of the transition metal film may not be etched because of the photoresist layer remaining on the first portion of the transition metal film. The remaining photoresist layer the first portion of the transition metal film can be removed leaving the transition metal film selectively formed on the first portion of the IGZO film.

As another example of a photoresist method, a light-sensitive material can be disposed on the transition metal film covering all or substantially of the IGZO film. A mask can cover a second portion of the photoresist layer that is aligned with the second portion of the IGZO film and the transition metal film, exposing a first portion of the photoresist layer that is aligned with a first portion of the IGZO film and the transition metal film. Light can be directed toward the substrate such that light is applied to the first portion of the photoresist layer, which can toughen the first portion of the photoresist layer (i.e., make the first portion etch-resistant). Light may not be applied to the second portion of the photoresist layer because of the mask. Then the second portion of the photoresist layer can be removed (e.g., via an etch process), exposing the second portion of the transition metal film aligned therewith. The second portion of the transition metal film can be selectively etched (e.g., via etch step 204 including etch cycle 210), exposing the second portion of the IGZO film. The first portion of the transition metal film may not be etched because the remaining photoresist can act as a mask over the first portion of the transition metal film to block the etchant. The remaining photoresist layer over the first portion of the IGZO film and the transition metal film can be removed (e.g., via etch), before and/or after etching the IGZO film (step 306).

In method 300 including step 304, the transition metal film on the first portion of the IGZO film can allow selective etching of the IGZO film (step 306). The transition metal film disposed on the first portion of the IGZO film can act as a mask of the first portion of the IGZO film. Therefore, applying an etchant (without an oxidant or oxidizing step) to the structure comprising the IGZO film and the transition metal film disposed on a first portion of the IGZO film can selectively etch the exposed second portion of the IGZO film. Remaining transition metal film can be etched, for example, via step 204 and etch cycle 210 (e.g., utilizing a relatively more reactive oxidant, such as ozone).

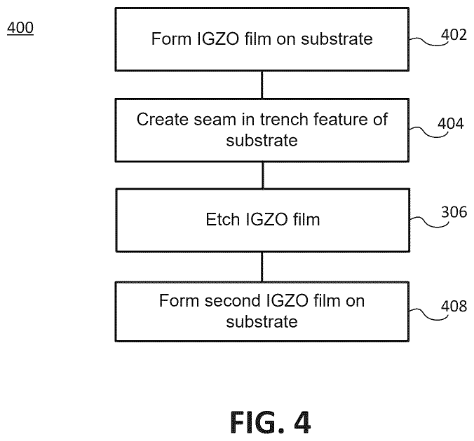

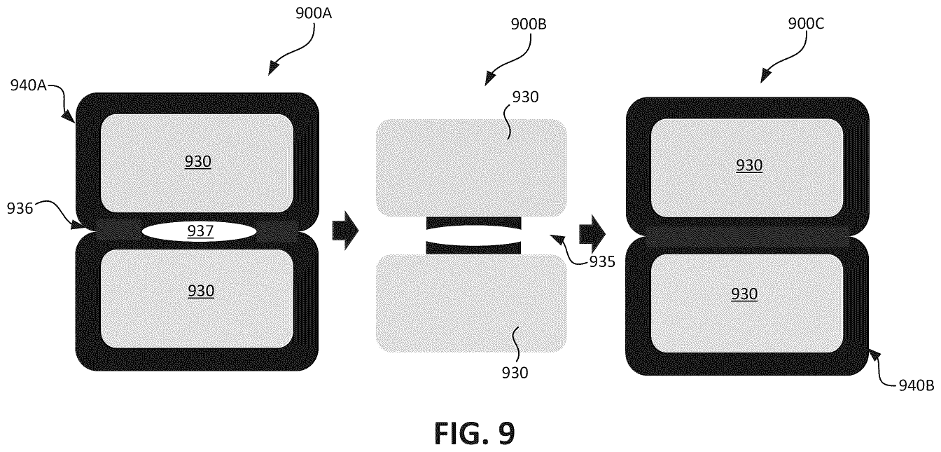

In various examples, in filling a trench feature of a substrate with an IGZO film, a seam or void can be formed therein. A void can be undesirable, affecting the resulting structure and properties thereof. With reference to FIGS. 4 and 9, in various examples, voids within layers and structures can be decreased, prevented, and/or removed, for example via method 400. Method 400 can comprise forming an IGZO film 940A on a substrate 930 (step 402) including within a trench feature 935 of substrate 930 (forming structure 900A). IGZO film 940 can pinch off at an inlet 936 of trench feature 935, creating a void or seam 937 in trench feature 935 of the substrate 930 (step 404). IGZO film 940A can be etched (step 406), for example, via the methods and/or etchants discussed herein, which can open and provide access to seam 937 (forming structure 900B). A second IGZO film 940B can be formed on substrate 930 (step 408). Second IGZO film 940B be disposed in seam 937, thus filling seam 937 (forming structure 900C). The structure resulting from method 400 can be void-free and/or seamless, and/or substantially void-free and/or seamless.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method, comprising:
performing an etch cycle on a transition metal film deposited on a substrate, the etch cycle comprising:
oxidizing the transition metal film, wherein the transition metal film comprises at least one of a transitional metal nitride or a transition metal; and
etching the oxidized transition metal film with an etchant comprising a metal halogen compound.

2. The method of claim 1, further comprising repeating the etch cycle multiple times.

3. The method of claim 1, wherein, in the etch cycle, the oxidizing the transition metal film step is repeated a desired number of times, and the etching the oxidized transition metal film step is repeated a second desired number of times.

4. The method of claim 1, wherein, one of:
the transition metal film comprises a transition metal nitride comprising at least one of titanium nitride, vanadium nitride, or nickel nitride; or
the transition metal film comprises a transition metal comprising molybdenum.

5. The method of claim 1, wherein the etchant comprises a transition metal chloride.

6. The method of claim 5, wherein the etchant comprises at least one of tungsten pentachloride, niobium chloride, or molybdenum chloride.

7. The method of claim 1, wherein the oxidizing the transition metal film comprises applying at least one of oxygen (O₂), ozone, peroxide, nitrous oxide, an alcohol, or water to the transition metal film.

8. The method of claim 1, further comprising, before the performing the etch cycle:
depositing an indium gallium zinc oxide (IGZO) film on the substrate;
selectively forming the transition metal film on a first portion of the IGZO film; and
selectively etching a second portion of the IGZO film with a first etchant comprising a metal halide.

9. The method of claim 8, wherein the second portion of the IGZO film does not comprise the transition metal film deposited thereon.

10. The method of claim 8, wherein the first etchant comprises tungsten pentachloride.

11. A method, comprising:
depositing an indium gallium zinc oxide (IGZO) film on a substrate; and
etching the IGZO film with a first etchant comprising a metal halide.

12. The method of claim 11, wherein the first etchant comprises tungsten pentachloride.

13. The method of claim 11, further comprising selectively forming a transition metal film on a first portion of the IGZO film before the etching the IGZO film step, wherein the etching the IGZO film step comprises selectively etching a second portion of the IGZO film, wherein the second portion of the IGZO film does not comprise the transition metal film deposited thereon.

14. The method of claim 13, wherein the transition metal film comprises at least one of a transitional metal nitride or a transition metal.

15. The method of claim 14, wherein the transition metal film comprises a transition metal nitride comprising at least one of titanium nitride, vanadium nitride, or nickel nitride.

16. The method of claim 14, wherein the transition metal film comprises a transition metal comprising molybdenum.

17. The method of claim 11, further comprising, before the etching the IGZO film:
depositing a transition metal film onto the IGZO film, wherein the transition metal film comprises at least one of a transitional metal nitride or a transition metal; and
selectively etching the transition metal film from a second portion of the IGZO film, such that the transition metal film is removed from the second portion of the IGZO film and the transition metal film is maintained on a first portion of the IGZO film.

18. The method of claim 17, further comprising oxidizing the transition metal film before the selectively etching the transition metal film,
wherein the selectively etching the transition metal film comprises etching the oxidized transition metal film with an etchant comprising a metal halogen compound.

19. The method of claim 18, wherein the etchant comprises at least one of tungsten pentachloride, niobium chloride, or molybdenum chloride.

20. A method, comprising:
depositing an indium gallium zinc oxide (IGZO) film in a gap feature of a substrate;
creating a seam in the gap feature in response to the depositing the IGZO film;
etching the IGZO film with an etchant comprising tungsten pentachloride to expose the seam; and
depositing a second IGZO film to fill the seam, such that the gap feature is filled with IGZO material without formation of a seam.
